(19) United States
(12) Patent Application Publication
(10) Pub. No.: US 2017/0147857 A1
(43) Pub. Date: May 25, 2017

(54) CHIP PACKAGE AND METHOD FOR FORMING THE SAME

(71) Applicant: XINTEC INC., Taoyuan City (TW)

(72) Inventor: Chien-Hung LIU, New Taipei City (TW)

(21) Appl. No.: 15/358,011

(22) Filed: Nov. 21, 2016

Related U.S. Application Data
(60) Provisional application No. 62/258,939, filed on Nov. 23, 2015.

(51) Int. Cl. G06K 9/00; H01L 21/48; H01L 23/00; H01L 23/31; H01L 21/52; H01L 21/56

(52) U.S. Cl. CPC G06K 9/00053; H01L 21/52; H01L 21/56; H01L 24/11; H01L 24/46; H01L 23/3121; H01L 24/17; H01L 21/4889; H01L 2224/1146

(57) ABSTRACT

A method for forming a chip package is provided. The method includes providing a device substrate including a sensing device and conductive pads that are exposed from a surface of the device substrate. The method further includes forming a conductive structure correspondingly on each of the conductive pads, and then covering the surface of the device substrate with a hard coating layer that completely covers the respective conductive structures on the conductive pads. The method further includes thinning the hard coating layer to expose the respective conductive structures on the conductive pads. The hard coating layer and the respective conductive structures on the conductive pads have substantially planar surfaces that are level with each other. A chip package is also provided.

### CROSS REFERENCE TO RELATED APPLICATIONS

This application claims the benefit of U.S. Provisional Application No. 62/258,939 filed on Nov. 23, 2015, the entirety of which is incorporated by reference herein.

### BACKGROUND OF THE INVENTION

Field of the Invention

The invention relates to chip package technology, and in particular to chip packages and methods for forming the same.

Description of the Related Art

As demand rises for electronic or optoelectronic products such as digital cameras, camera phones, bar code readers, and monitors, the semiconductor technology used in the aforementioned products must develop rapidly, as product trends require miniaturization of the semiconductor chip, as well as requiring that the functionality of the semiconductor chip be increased and complex.

Most semiconductor chips are typically placed in a sealed package, due to performance demands, for operational stability. Therefore, the chip package process is an important process for the fabrication of electronic products. The chip package not only protects the chip therein from ambient contamination, but it also provides electrical connections between the interior electronic devices and the exterior circuits. However, with the complicated functionality of the electronic or optoelectronic products, the difficulty of formation of the packages is increased and/or the reliability of the packages is reduced.

FIG. 1 is a cross-sectional view of an exemplary embodiment of a chip package 10. A method for forming the chip package 10 includes mounting a chip 100 (e.g., a sensor chip) onto a package substrate 200. Next, a wire bonding process is performed, so that wires 102 are electrically connected between the conductive pads 100a of the chip 100 and the conductive pads 200a of the package substrate 200. Thereafter, a molding process is performed to form an encapsulation layer 104 that encapsulates the package substrate 200, the wires 102 and a portion of the chip 100, so that the sensing region of the chip 100 is exposed. Finally, a hard coating layer 106 is formed on the surface of the encapsulation layer 104 and the sensing region of the chip 100 by a spray coating process, so as to protect the sensing region of the chip 100.

However, since there is a difference in the step height between the encapsulation layer 104 and chip 100 and since the material of the hard coating layer 106 is flowable before being cured, the thickness of the cured hard coating layer 106 is nonuniform, thereby impacting the performance and reliability of the chip package 10.

Accordingly, there exists a need in the art for development of a chip package and methods for forming the same capable of eliminating or mitigating the aforementioned problems.

### BRIEF SUMMARY OF THE INVENTION

An embodiment of the invention provides a method for forming a chip package which includes providing a device substrate including a sensor device and a plurality of conductive pads that is exposed from a surface of the device substrate. A conductive structure is correspondingly formed on each of the plurality of conductive pads. The surface of the device substrate is covered with a hard coating layer that completely covers the conductive structure on each of the plurality of conductive pads. The hard coating layer is thinned to expose the conductive structure on each of the plurality of conductive pads, so that the hard coating layer and the conductive structure on each of the plurality of conductive pads have substantially planar surfaces that are level with each other.

An embodiment of the invention provides a chip package which includes a device substrate including a sensor device and a plurality of conductive pads that is exposed from a surface of the device substrate. A hard coating layer covers the surface of the device substrate and has a plurality of openings that respectively expose the plurality of conductive pads. A plurality of conductive structures is correspondingly disposed in the plurality of openings to be electrically connected to the plurality of conductive pads. The hard coating layer and the plurality of conductive structures have substantially planar surfaces that are level with each other.

### BRIEF DESCRIPTION OF THE DRAWINGS

The present invention can be more fully understood by reading the subsequent detailed description and examples with references made to the accompanying drawings, wherein:

FIG. 1 is a cross-sectional view of an exemplary embodiment of a chip package.

FIGS. 2A to 2C are cross-sectional views of an exemplary embodiment of various intermediate stages for forming a chip package according to the invention.

FIGS. 3A to 3D are cross-sectional views of another exemplary embodiment of various intermediate stages for forming a chip package according to the invention.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. In addition, the present disclosure may repeat reference numbers and/or letters in the various embodiments. This repetition is for the purpose of simplicity and clarity, and does not imply any relationship between the different embodiments and/or configurations discussed. Furthermore, when a first material layer is referred to as being on or overlying a second material layer, the first material layer may be in direct contact with the second material layer, or spaced apart from the second material layer by one or more material layers.

A chip package according to an embodiment of the present invention may be used to package micro-electro-mechanical system chips. However, embodiments of the invention are not limited thereto. For example, the chip package of the embodiments of the invention may be implemented to package active or passive devices or electronic components of integrated circuits, such as digital or analog circuits. For example, the chip package is related to optoelectronic devices, micro-electro-mechanical systems (MEMS), biometric devices, micro fluidic systems, and physical sensors measuring changes to physical quantities such as heat, light, capacitance, pressure, and so on. In particular, a wafer-level package (WSP) process may optionally be used to package semiconductor chips, such as image-sensor elements, light-emitting diodes (LEDs), solar cells, RF circuits, accelerators, gyroscopes, fingerprint recognition devices, micro actuators, surface acoustic wave devices, pressure sensors, ink printer heads, and so on.

The above-mentioned wafer-level package process mainly means that after the packaging step is accomplished during the wafer stage, the wafer with chips is cut to obtain individual packages. However, in a specific embodiment, separated semiconductor chips may be redistributed on a carrier wafer and then packaged, which may also be referred to as a wafer-level package process. In addition, the above-mentioned wafer-level package process may also be adapted to form a chip package having multilayer integrated circuit devices or system in package (SIP) by stacking (stack) a plurality of wafers having integrated circuits.

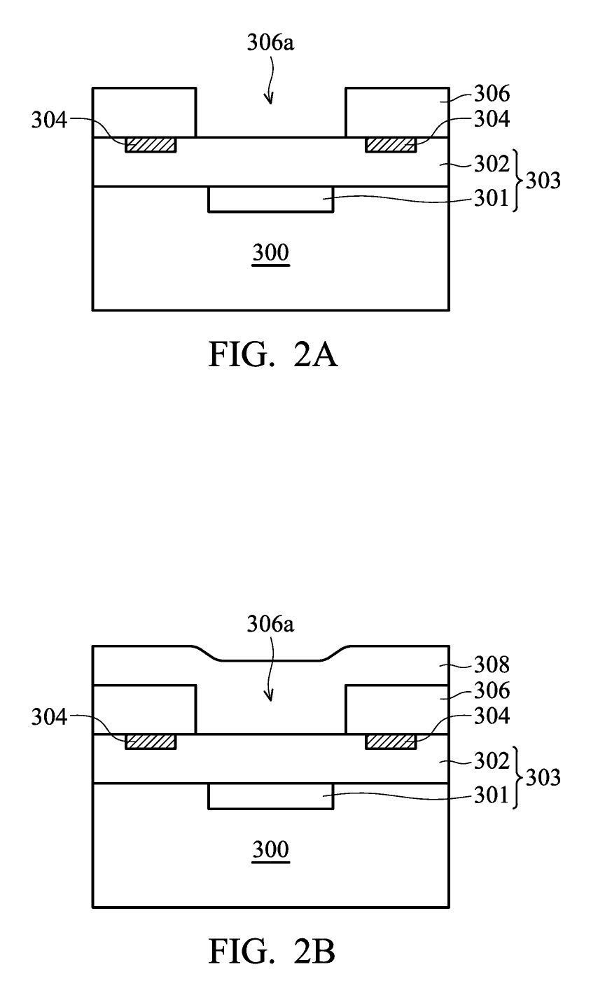

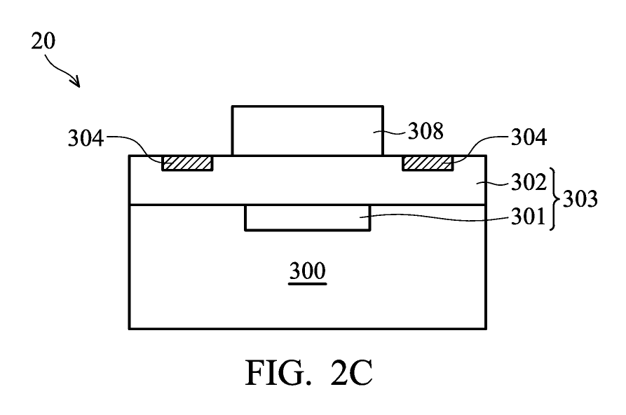

Refer to FIG. 2C, which is a cross-sectional view of an exemplary embodiment of a chip package 20 according to the invention. In the embodiment, the chip package 20 includes a device substrate 303. In the embodiment, the device substrate 303 includes a body 300 and a metallization layer 302 formed on the body 300. In one embodiment, the body 300 may include a silicon or another semiconductor body. Moreover, the metallization layer 302 may include a dielectric material layer and interconnect structures (not shown) disposed in the dielectric material layer.

In the embodiment, the body 300 of the device substrate 303 has a sensor device 301 that is adjacent to the lower surface of the metallization layer 302. In one embodiment, the sensor device 301 is configured to sense biometrics and may include a fingerprint-recognition device. In some embodiments, the sensor device 301 is configured to sense environmental characteristics and may include a capacitance-sensing element, or another suitable sensing element.

Moreover, the metallization layer 302 of the device substrate 303 may include one or more conductive pads 304 therein. Typically, the conductive pads 304 disposed in the metallization layer 302 may be an uppermost metal layer that is exposed from a surface of the device substrate 303 (e.g., the upper surface of the metallization layer 302). In one embodiment, the sensing element in the sensor device 301 may be electrically connected to the conductive pads 304 via the interconnect structures in the metallization layer 302.

In one embodiment, the conductive pad 304 may be formed of a single conductive layer or multiple conductive layers. To simplify the diagram, only two conductive pads 304 formed of a single conductive layer in the device substrate 303 are depicted herein as an example (as shown in FIG. 2C).

In the embodiment, the chip package 20 further includes a hard coating layer 308 that is disposed on the surface of the device substrate 303 and directly above the sensor device 301. The hard coating layer 308 acts as a protective layer for the sensor device 301 and the conductive pads 304 of the device substrate 303 are exposed from the hard coating layer 308. In one embodiment, the hard coating layer 308 may include a high hardness material with a hardness scale (i.e., Mohs Hardness Scale) that is not less than 6. Moreover, the hard coating layer 308 may include dimethylacetamide (DMAC), strontium titanate, titanium dioxide, or another suitable insulating protective material with a high dielectric constant.

Refer to FIGS. 2A to 2C, which are cross-sectional views of an exemplary embodiment of various intermediate stages for forming a chip package 20 according to the invention. As shown in FIG. 2A, a device substrate 303 that includes a body 300 and a metallization layer 302 formed on the body 300 is provided. In one embodiment, the body 300 may include a silicon or another semiconductor body. Moreover, the metallization layer 302 may include a dielectric material layer and interconnect structures (not shown) disposed in the dielectric material layer. In one embodiment, the device substrate 303 is a chip. In another embodiment, the device substrate 303 is a wafer for facilitating the wafer-level packaging process. In the embodiment, the device substrate 303 includes chip regions. To simplify the diagram, only a single chip region of the device substrate 303 is depicted herein.

In the embodiment, the chip region of the device substrate 303 has a sensor device 301 and one or more conductive pads 304 therein. Typically, the sensor device 301 is disposed in the body 300. The conductive pad 304 is disposed in the metallization layer 302 and may be an uppermost metal layer that is adjacent to the upper surface of the metallization layer 302. In one embodiment, the sensing element in the sensor device 301 (e.g., a fingerprint-recognition device) may be electrically connected to the conductive pads 304 via the interconnect structures in the metallization layer 302. In one embodiment, the conductive pad 304 may be formed of a single conductive layer or multiple conductive layers. To simplify the diagram, only two conductive pads 304 formed of a single conductive layer in the device substrate 303 are depicted herein as an example.

Next, the surface of the device substrate 303 is covered by a photoresist material layer (not shown). Thereafter, the photoresist material layer is patterned by a photolithography process, so as to form a photoresist pattern layer 306. In the embodiment, the photoresist pattern layer 306 has an opening 306 that exposes the surface of the device substrate 303 and corresponds to the sensing device 301 of the device substrate 303. In the embodiment, the photoresist pattern layer 306 is used for patterning a subsequent hard coating layer which is hard to etch.

Refer to FIG. 2B, in which a hard coating layer 308 is formed on the photoresist pattern layer 306 and fully fills the opening 306a of the photoresist pattern layer 306. The hard coating layer 308 on the photoresist pattern layer 306 has a thickness in a range of about 5 μm to 30 μm. In one embodiment, the hard coating layer 308 may include a high hardness material with a hardness scale (i.e., Mohs Hardness Scale) that is not less than 6. Moreover, the hard coating layer 308 may include DMAC, strontium titanate, titanium dioxide, or another suitable insulating protective material with a high dielectric constant.

Refer to FIG. 2C. As mentioned above, since the hard coating layer 308 is hard to etch, a lift-off process is performed using the photoresist pattern layer 306 as a sacrificial material, so as to remove the portion of the hard coating layer 308 on the photoresist pattern layer 306. For example, through holes (not shown) are formed in the hard coating layer 308 by oxygen plasma, so that the photoresist pattern layer 306 under the hard coating layer 308 is exposed. Next, the photoresist pattern layer 306 is removed by wet etching through these through holes, so that the portion of the hard coating layer 308 on the photoresist pattern layer 306 is simultaneously removed, but the portion of the hard coating layer 308 on the sensor device 301 is left. The left hard coating layer 308 serves as a protective layer for the underlying sensor device 301.

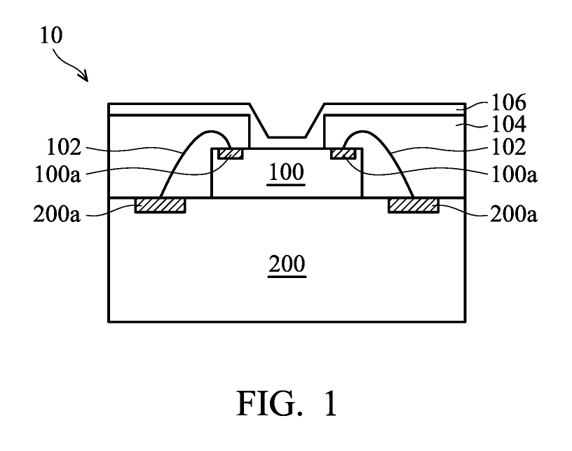

Compared to the chip package 10 shown in FIG. 1, the protective layer (i.e., the hard coating layer 308) of the chip package 20 is formed by a lift-off process prior to performing the wire bonding process and the molding process. Accordingly, the formed hard coating layer 308 has a thickness with good uniformity, thereby maintaining or improving the performance and reliability of the chip package 20.

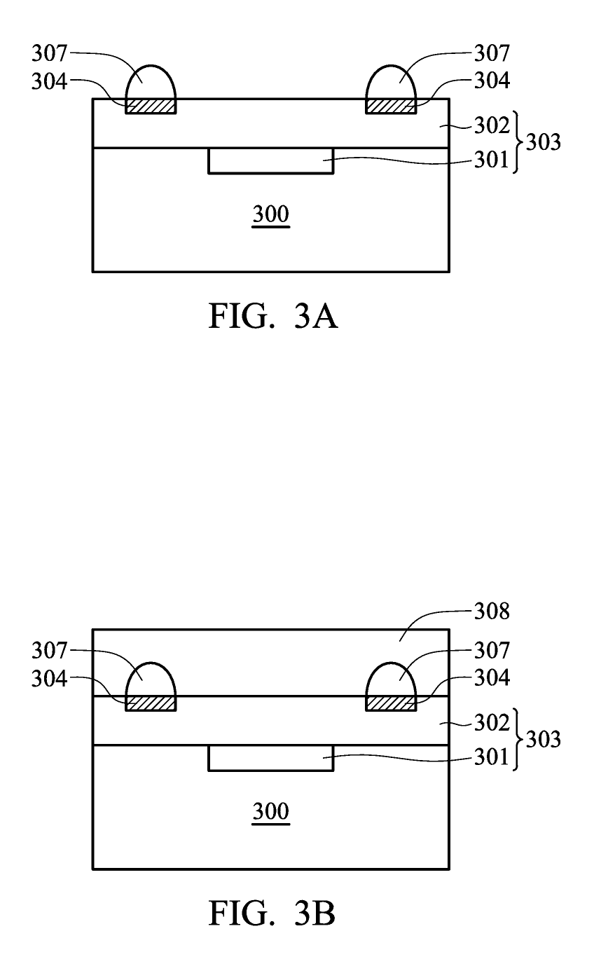

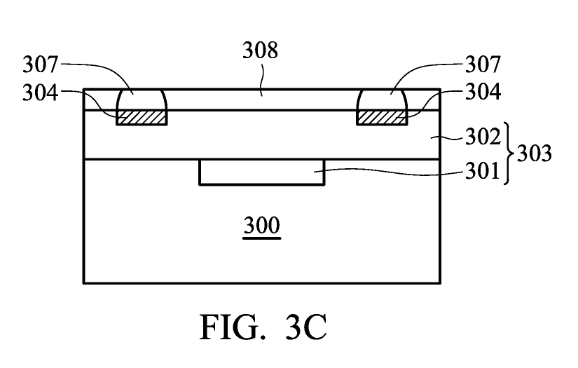

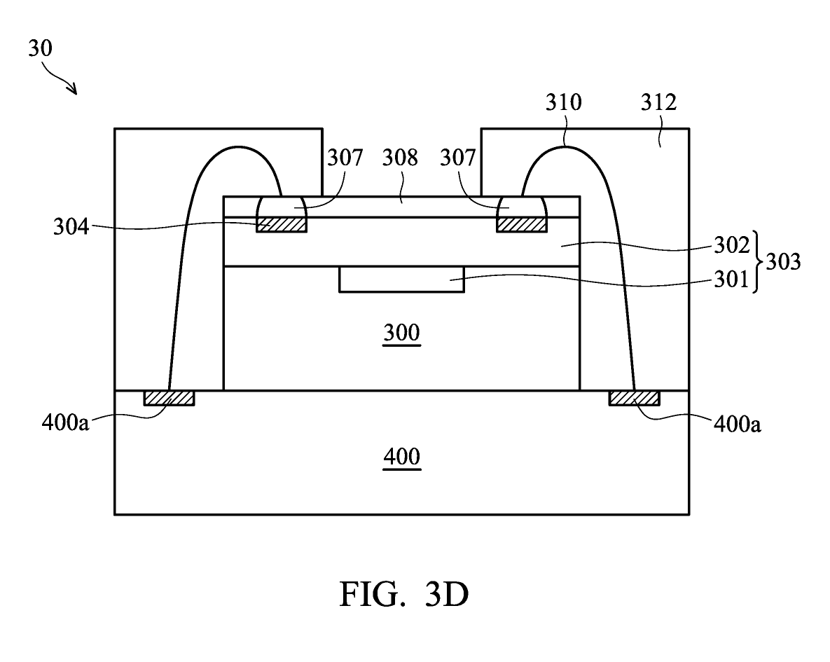

Refer to FIG. 3D, which is a cross-sectional view of another exemplary embodiment of a chip package 30 according to the invention. Elements in FIG. 3D that are the same as those in FIG. 2C are labeled with the same reference numbers as in FIG. 2C and are not described again for brevity. In the embodiment, the chip package 30 includes a device substrate 303. As mentioned in the embodiment of FIG. 2C, the device substrate 303 includes a body 300 and a metallization layer 302 formed on the body 300. The body 300 of the device substrate 303 has a sensor device 301 that is adjacent to the lower surface of the metallization layer 302 and may include a fingerprint-recognition device. The metallization layer 302 of the device substrate 303 may include one or more conductive pads 304 therein, in which the conductive pads 304 are exposed from a surface of the device substrate 303 and electrically connected to the sensing element in the sensor device 301 via the interconnect structures (not shown) in the metallization layer 302.

In one embodiment, the conductive pad 304 may be formed of a single conductive layer or multiple conductive layers. To simplify the diagram, only two conductive pads 304 formed of a single conductive layer in the device substrate 303 are depicted herein as an example (as shown in FIG. 3D).

In the embodiment, the chip package 30 further includes a hard coating layer 308 that covers the surface of the device substrate 303. Unlike the embodiment of FIG. 2C, the hard coating layer 308 has openings corresponding to the conductive pads 304 and exposing the conductive pads 304. As mentioned in the embodiment of FIG. 2C, the hard coating layer 308 may include a high hardness material with a hardness scale that is not less than 6. Moreover, the hard coating layer 308 may include DMAC, strontium titanate, titanium dioxide, or another suitable insulating protective material with high dielectric constant.

In the embodiment, the chip package 30 further includes conductive structures 307 correspondingly disposed in the openings of the hard coating layer 308, so as to be electrically connected to the conductive pads 304. Moreover, the hard coating layer 308 and the conductive structures 307 have substantially planar surfaces that are level with each other. For example, the upper surfaces of the hard coating layer 308 and the conductive structures 307 are coplanar, and the lower surfaces of the hard coating layer 308 and the conductive structures 307 are also coplanar. In one embodiment, the conductive structures 307 include metal bumps or metal pillars. Moreover, the conductive structures 307 are formed of gold, silver, tin, copper or an alloy thereof.

In the embodiment, the chip package 30 further includes a package substrate 400 having conductive pads 400a thereon. The device substrate 303 is mounted onto the package substrate 400. In the embodiment, the chip package 30 further includes an encapsulation layer 312 and wires 310 embedded in the encapsulation layer 312. The encapsulation layer 312 is disposed on the package substrate 400 to encapsulate the hard coating layer 308 and the device substrate 303. The encapsulation layer 312 includes an opening, so that a portion of the hard coating layer 308 corresponding to the sensor device 301 is exposed from the encapsulation layer 312. In the embodiment, the encapsulation layer 312 may comprise epoxy resin, inorganic materials (such as silicon oxide, silicon nitride, silicon oxynitride, metal oxide or a combination thereof), organic polymer materials (such as polyimide, butylcyclobutene (BCB), parylene, polynaphthalenes, fluorocarbons or acrylates), or another suitable insulating material.

In the embodiment, the wires 310 embedded in the encapsulation layer 312 are electrically connected between the conductive structures 307 in the hard coating layer 308 and the conductive pads 400a of the package substrate 400.

Refer FIGS. 3A to 3D, which are cross-sectional views of another exemplary embodiment of various intermediate stages for forming a chip package 30 according to the invention. Elements in FIGS. 3A to 3D that are the same as those in FIGS. 2A to 2C are labeled with the same reference numbers as in FIGS. 2A to 2C and are not described again for brevity. As shown in FIG. 3A, a device substrate 303 that includes a body 300 and a metallization layer 302 formed on the body 300 is provided. In one embodiment, the device substrate 303 is a chip. In another embodiment, the device substrate 303 is a wafer for facilitating the wafer-level packaging process. In the embodiment, the device substrate 303 includes chip regions. To simplify the diagram, only a single chip region of the device substrate 303 is depicted herein.

In the embodiment, the chip region of the device substrate 303 has a sensor device 301 that is adjacent to the lower surface of the metallization layer 302 and may include a fingerprint-recognition device. The metallization layer 302 of the device substrate 303 has one or more conductive pads 304 therein, in which the conductive pads 304 are exposed from a surface of the device substrate 303 and electrically connected to the sensing element in the sensor device 301 via the interconnect structures (not shown) in the metallization layer 302. To simplify the diagram, only two conductive pads 304 formed of a single conductive layer in the device substrate 303 are depicted herein as an example.

Next, a conductive structure 307 is correspondingly formed on each of the conductive pads 304, so as to serve as an extension portion or a conductive channel. In one embodiment, the conductive structure 307 includes metal bumps or metal pillars. Moreover, the conductive structure 307 is formed of gold, silver, tin, copper or an alloy thereof. In one embodiment, the conductive structure 307 is formed by a ball bumping process. In some embodiments, the conductive structure 307 is formed by a plating process, a sputtering process, or another suitable deposition process.

Refer to FIG. 3B, in which a hard coating layer 308 covers the surface of the device substrate 303 and entirely covers the conductive structure 307 on each of the conductive pads 304. Namely, the conductive structures 307 are entirely embedded in the hard coating layer 308 and are not exposed from the surface of the hard coating layer 308. In one embodiment, the hard coating layer 308 is formed by a printing or coating process. As mentioned above, the hard coating layer 308 may include a high hardness material with a hardness scale that is not less than 6. Moreover, the hard coating layer 308 may include a material with a high dielectric constant that is greater than 5. For example, the hard coating layer 308 may include DMAC, strontium titanate, titanium dioxide, or another suitable insulating protective material with a high dielectric constant.

Refer to FIG. 3C, in which a thinning or planarization process is performed on the hard coating layer 308 to expose the conductive structure 307 on each of the conductive pads 304. For example, the thinning process may include a chemical mechanical polishing (CMP) process, a mechanical grinding process, or another suitable planarization process. After the thinning process is performed, the hard coating layer 308 and the conductive structures 307 have substantially planar surfaces that are level with each other. For example, the upper surfaces of the hard coating layer 308 and the conductive structures 307 are coplanar.

Refer to FIG. 3D, in which a package substrate 400 having conductive pads 400a is provided. The structure shown in FIG. 3C is mounted onto the package substrate 400. Next, a wire bonding process is performed, such that wires 310 are electrically connected between the conductive structures 307 in the hard coating layer 308 and the conductive pads 400a of the package substrate 400. Thereafter, a molding process is performed to form an encapsulation layer 312 on the package substrate 400 to encapsulate the hard coating layer 308, the device substrate 303, and the wires 310. The encapsulation layer 312 includes an opening, so that a portion of the hard coating layer 308 corresponding to the sensor device 301 is exposed from the encapsulation layer 312.

According to the embodiments of FIGS. 3A to 3D, since a planarization process is used for the fabrication of the protective layer (i.e., the hard coating layer 308) of the chip package 30 and the protective layer is formed prior to performing the wire bonding process and the molding process, the hard coating layer 308 has a thickness with better uniformity than that of chip package 10 shown in FIG. 1. As a result, the performance and reliability of the chip package 20 can be maintained or improved. Moreover, as mentioned above, since a planarization process is used for the fabrication of the hard coating layer 308, there is no need to perform lithography and lift-off processes. Compared to the chip package 20 shown in FIG. 2, the fabrication can be simplified further and the manufacturing cost can be reduced further. Additionally, since the surfaces of the hard coating layer 308 and the conductive structures 307 are substantially coplanar, it is advantageous for subsequently performing wire bonding and molding processes for the chip package 30.

While the invention has been disclosed in terms of the preferred embodiments, it is not limited. The various embodiments may be modified and combined by those skilled in the art without departing from the concept and scope of the invention.

What is claimed is:

1. A chip package, comprising:
a device substrate comprising a sensor device and a plurality of conductive pads that is exposed from a surface of the device substrate;
a hard coating layer covering the surface of the device substrate and having a plurality of openings that respectively exposes the plurality of conductive pads; and
a plurality of conductive structures correspondingly disposed in the plurality of openings to be electrically connected to the plurality of conductive pads, wherein the hard coating layer and the plurality of conductive structures have substantially planar surfaces that are level with each other.

2. The chip package as claimed in claim 1, wherein the sensor device comprises a fingerprint-recognition device.

3. The chip package as claimed in claim 2, wherein the hard coating layer comprises a high hardness material with a hardness scale that is not less than 6.

4. The chip package as claimed in claim 1, wherein the hard coating layer comprises a material with a high dielectric constant that is greater than 5.

5. The chip package as claimed in claim 1, wherein the hard coating layer comprises dimethylacetamide.

6. The chip package as claimed in claim 1, wherein the plurality of conductive structures comprises metal bumps or metal pillars.

7. The chip package as claimed in claim 6, wherein the plurality of conductive structures comprises gold, silver, tin, copper or an alloy thereof.

8. The chip package as claimed in claim 1, further comprising:
a package substrate mounted under the device substrate;
an encapsulation layer disposed on the package substrate to encapsulate the hard coating layer and the device substrate, wherein a portion of the hard coating layer corresponding to the sensor device is exposed from the encapsulation layer; and
a plurality of wires embedded in the encapsulation layer and electrically connected between the plurality of conductive structures and the package substrate.

9. A method for forming a chip package, comprising:
providing a device substrate comprising a sensor device and a plurality of conductive pads that is exposed from a surface of the device substrate;
correspondingly forming a conductive structure on each of the plurality of conductive pads;
covering the surface of the device substrate with a hard coating layer that completely covers the conductive structure on each of the plurality of conductive pads; and
thinning the hard coating layer to expose the conductive structure on each of the plurality of conductive pads, so that the hard coating layer and the conductive structure on each of the plurality of conductive pads have substantially planar surfaces that are level with each other.

10. The method as claimed in claim 9, wherein the sensor device comprises a fingerprint-recognition device.

11. The method as claimed in claim 9, wherein the hard coating layer comprises a high hardness material with a hardness scale that is not less than 6.

12. The method as claimed in claim 9, wherein the hard coating layer comprises a material with a high dielectric constant that is greater than 5.

13. The method as claimed in claim 9, wherein the hard coating layer comprises dimethylacetamide.

14. The method as claimed in claim 9, wherein the plurality of conductive structures comprises metal bumps or metal pillars.

15. The method as claimed in claim 14, wherein the plurality of conductive structures comprises gold, silver, tin, copper or an alloy thereof.

16. The method as claimed in claim 9, wherein the conductive structure is formed by a ball bumping process.

17. The method as claimed in claim 9, wherein the conductive structure is formed by a plating process.

18. The method as claimed in claim 9, wherein the step of thinning the hard coating layer comprises performing a chemical mechanical polishing process.

19. The method as claimed in claim 9, further comprising:
mounting the device substrate onto a package substrate;
forming a plurality of wires, such that the plurality of wires is electrically connected between the plurality of conductive structures and the package substrate; and
forming an encapsulation layer on the package substrate to encapsulate the hard coating layer, the device substrate, and the plurality of wires, wherein a portion of the hard coating layer corresponding to the sensor device is exposed from the encapsulation layer.
